(19) United States
(12) Patent Application Publication
(10) Pub. No.: US 2005/0112824 A1
(43) Pub. Date: May 26, 2005

(54) Method of forming gate oxide layers with multiple thicknesses on substrate

(76) Inventors: Yu-Chang Jong, Taipei City (TW); Ruey-Hsin Liu, Miaoli City (TW); Yi-Chun Lin, Hsinchu (TW); Shun-Liang Hsu, Taipei City (TW); Chen-Bau Wu, Taipei City (TW); Kuo-Ming Wu, Hsinchu (TW)

Correspondence Address: THOMAS, KAYDEN, HOSTEMEYER & RISLEY LLP, 100 GALLERIA PARKWAY, SUITE 1750, ATLANTA, GA, 30339, US

(21) Appl. No.: 10/723,794

(22) Filed: Nov. 26, 2003

(51) Int. Cl. H01L 21/8234; H01L 21/336

(52) U.S. Cl. 438/275; 438/279

(57) ABSTRACT

A method of forming gate dielectric layers with various thicknesses on a substrate. At least a first active region and a second active region are provided on the substrate. A first thermal oxide layer is formed on the substrate. A blanket dielectric layer with a first thickness is deposited overlying the substrate. The dielectric layer and the underlying first thermal oxide layer on the second active region are removed to expose the substrate. A second thermal oxide layer with a second thickness less than the first thickness is formed on the second active region. A first gate is formed on the dielectric layer on the first active region and a second gate is formed on the second thermal oxide layer on the second active region.

### BACKGROUND

The present invention relates to a semiconductor process, and particularly to a method of forming gate oxide layers with multiple thicknesses on a substrate.

In order to increase the performance of integrated circuits (ICs), circuit designers often require gate devices with various characteristics. Such various characteristics can be achieved with different gate dielectric layer thicknesses, such that the gate devices can be operated at differing voltage levels. Conventionally, high voltage devices are formed on a wafer with a relatively thick gate dielectric layer to prevent breakdown during the high voltage operation. On the other hand, low voltage devices are formed on the same wafer with a relatively thin gate dielectric layer to increase the speed of the circuit.

FIGS. 1a to 1d are cross-sections showing a conventional method of forming integrated circuit gate dielectric layers with multiple thicknesses. In FIG. 1a, a substrate 100, such as a silicon wafer, is provided. A plurality of shallow trench isolation (STI) structures 102 composed of oxides is formed within the substrate 100. As a result, active regions 10 and 20 are defined on the substrate 100 and separated from each other by the isolation structure 102. Here, the active region 10 is used as a device region for high voltage operation, such as a power device region. Moreover, the active region 20 is used as a device region for low voltage operation, such as an input/output (I/O) or core device region.

In FIG. 1b, conventional thermal oxidation is performed on the substrate 100 to form a relatively thick oxide layer 104 on the active regions 10 and 20. The formed oxide layer 104 is used as a gate dielectric layer for the subsequent high voltage device fabrication. Next, a photoresist layer 106 is formed overlying the oxide layer 104 and the STI structures 102, which has an opening 107 over the active region 20 to expose the overlying oxide layer 104. However, a high voltage (for example, 40V) device commonly requires a gate dielectric layer with a thickness more than 1000 Å to prevent breakdown during high voltage operation. The gate dielectric layer formed by conventional thermal oxidation may greatly increase the thermal budget, thus increasing the fabricating cost. Moreover, the thick thermal oxide layer 104 causes the corners 102a of the STI structures 102 to round off, negatively impacting device properties and narrowing the areas of the active regions 10 and 20.

Next, in FIG. 1c, the exposed oxide layer 104 on the active region 20 is removed by, for example, wet chemical etching using the hydrofluoric acid (HF) as an etchant. During the wet etching, the STI structures 102 composed oxides are also etched, resulting in the loss of a portion of the STI structures 102, depicted as the recess regions 102b in FIG. 1c. The recess regions 102b may expose a portion of the active region 20 at the corners, inducing leakage current and decreasing device reliability.

Finally, in FIG. 1d, after the photoresist layer 106 is stripped by conventional process, thermal oxidation is performed on the exposed substrate 100 on the active region 20 to form a relatively thin oxide layer 108 thereon. Thereafter, the poly gates 110 and 112 are respectively formed on the gate dielectric layers corresponding to the active region 10 and the active region 20 by conventional processes to complete the high and low voltage gate devices fabrication.

U.S. Pat. No. 5,672,561 to Barsan et al. discloses a method of forming gate oxide layers with multiple thicknesses on a wafer substrate, which employs multiple doping regions with various impurities to prompt or retard the thermal oxidation on each doping region. As mentioned above, however, this approach still uses thermal oxidation to form the gate oxide layer. Since the thickness of the gate oxide layer for high voltage devices is greater than 1000 Å, the thermal budget is greatly increased. Moreover, it is difficult to form suitable gate oxide thicknesses for the low voltage devices while simultaneously forming the gate oxide layers for the high and low voltage devices, even when using nitrogen ion implantation to retard oxide formation on the low voltage device region.

Additionally, U.S. Pat. No. 6,541,321 to Buller et al. discloses a method for forming multiple gate oxide layers with the plasma oxygen doping, while U.S. Pat. No. 6,593,182 to Chen discloses a method of making transistors with gate insulation layers of differing thickness. Such methods use oxygen or fluorine atoms to prompt the thermal oxidation, thereby forming gate dielectric layers with different thicknesses. Also, however, the thermal budget and other problems as mentioned above still cannot be effectively solved.

It is therefore apparent that the art is in need of an improved process capable of solving problems, so as to increase reliability of ICs having gate devices with different operation voltage levels.

### SUMMARY

Accordingly, one object of the present invention is to form gate devices with multiple thickness dielectric layers on a substrate for different operation voltage levels.

Another object of the present invention is to form gate dielectric layers with various thickness on a substrate using a composite oxide as the gate dielectric layer for the high voltage device, thereby reducing thermal budget and preventing the formation of recesses in shallow trench isolation (STI) regions.

The above and other objects and advantages, which will be apparent to one of skill in the art, are achieved in the present invention which is directed to, in a first aspect, a method of forming dielectric layers with various thicknesses on a substrate. First, a first device region and a second device region are provided on the substrate. Next, a first oxide layer is grown on the substrate. A dielectric layer with a first thickness is subsequently deposited on the first oxide layer. Thereafter, the dielectric layer and the underlying first oxide layer on the second device region are removed to expose the substrate. Finally, a second oxide layer with a second thickness less than the first thickness is formed on the substrate of the second device region.

In another aspect of the invention, a method of forming gate dielectric layers with various thicknesses on a substrate is provided. First, a first active region and a second active region are provided on the substrate, Next, a first thermal oxide layer is formed on the substrate. A blanket dielectric layer with a first thickness is deposited overlying the substrate. Next, a first masking layer is formed overlying the substrate except over the second active region. The dielectric layer and the underlying first thermal oxide layer on the second active region are successively etched using the first masking layer as an etch mask to expose the substrate. The first masking layer is subsequently removed. Thereafter, a second thermal oxide layer with a second thickness less than the first thickness is formed on the second active region. Finally, a first gate is formed on the dielectric layer on the first active region and a second gate is formed on the second thermal oxide layer on the second active region.

In yet another aspect of the invention, a method of forming an integrated circuit having gate oxide layers with multiple thicknesses is provided. First, a substrate having a first active region, a second active region, and a third active region is provided. A first oxidation is performed to form a first oxide layer on the substrate and a blanket high temperature oxide layer with a first thickness is then deposited overlying the substrate. Next, a first photoresist layer is formed on the high temperature oxide layer except over the second active region. The high temperature oxide layer and the underlying first oxide layer on the second active region are successively etched using the first photoresist layer as an etch mask to expose the substrate, and the first photoresist layer is then removed. Next, a second oxidation is performed to form a second oxide layer with a second thickness less than the first thickness on the second active region, Next, a second photoresist layer is formed overlying the substrate except over the third active region. Thereafter, the high temperature oxide layer and the underlying first oxide layer on the third active region are successively etched to expose the substrate, and the second photoresist layer is then removed. Next, a third oxidation is performed to form a third oxide layer with a third thickness less than the first thickness on the third active region and on the second oxide layer on the second active region. Finally, a first gate is formed on the high temperature oxide layer on the first active region, a second gate is formed on the second oxide layer on the second active region, and a third gate is formed on the third thermal oxide layer on the third active region.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIGS. 1a to 1d are cross-sections showing a conventional method of forming an integrated circuit having gate dielectric layers with multiple thicknesses.

FIGS. 2a to 2e are cross-sections showing a method of forming an integrated circuit having gate dielectric layers with multiple thicknesses according to the invention.

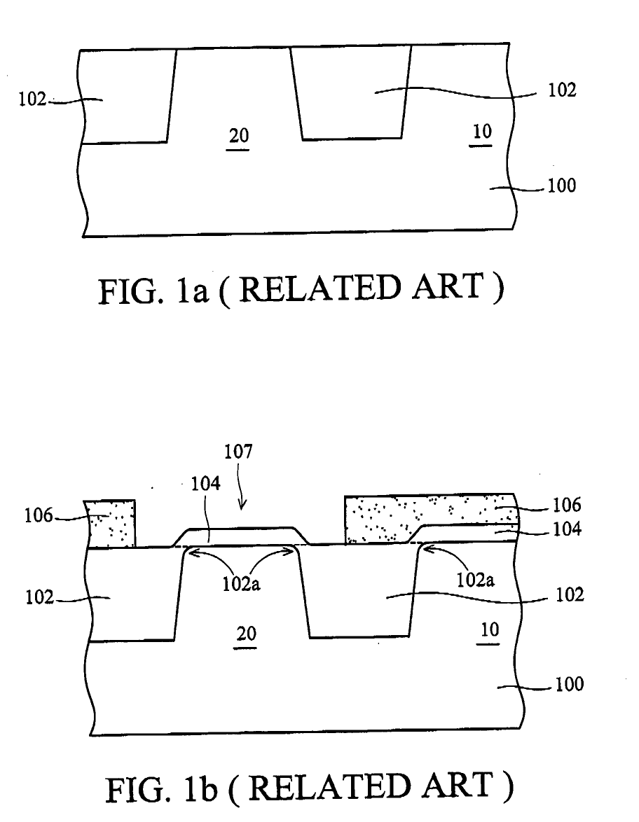

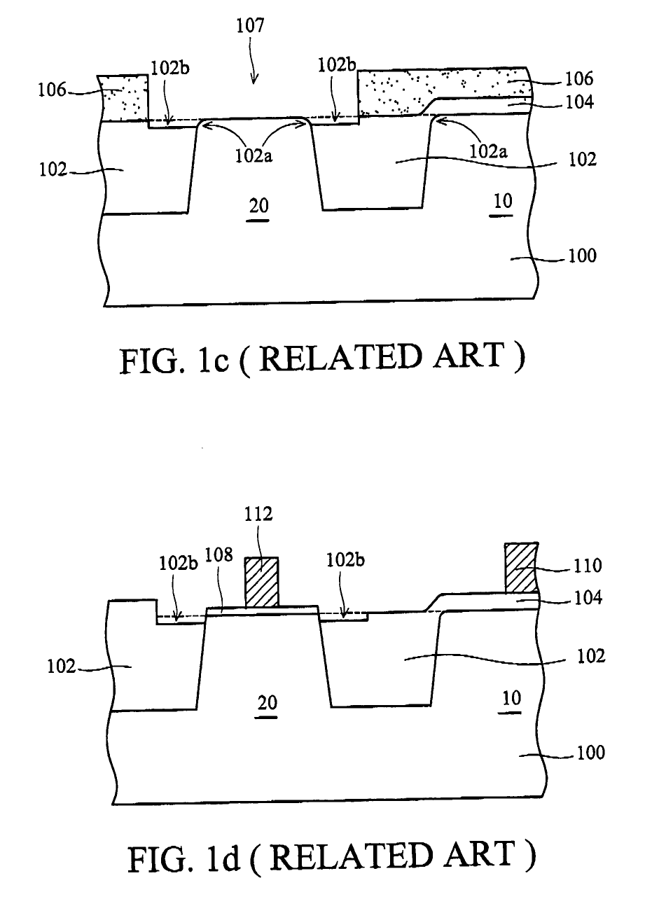

### DESCRIPTION

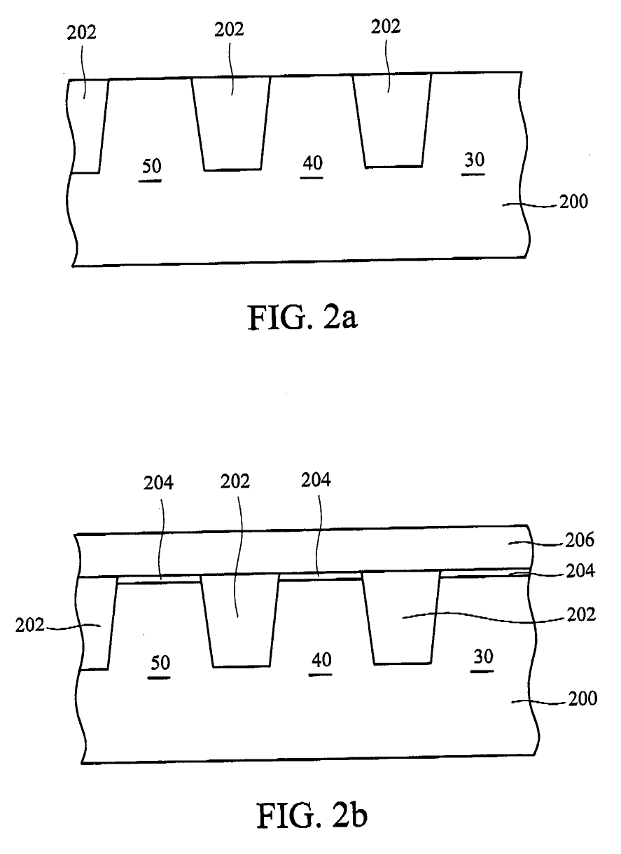

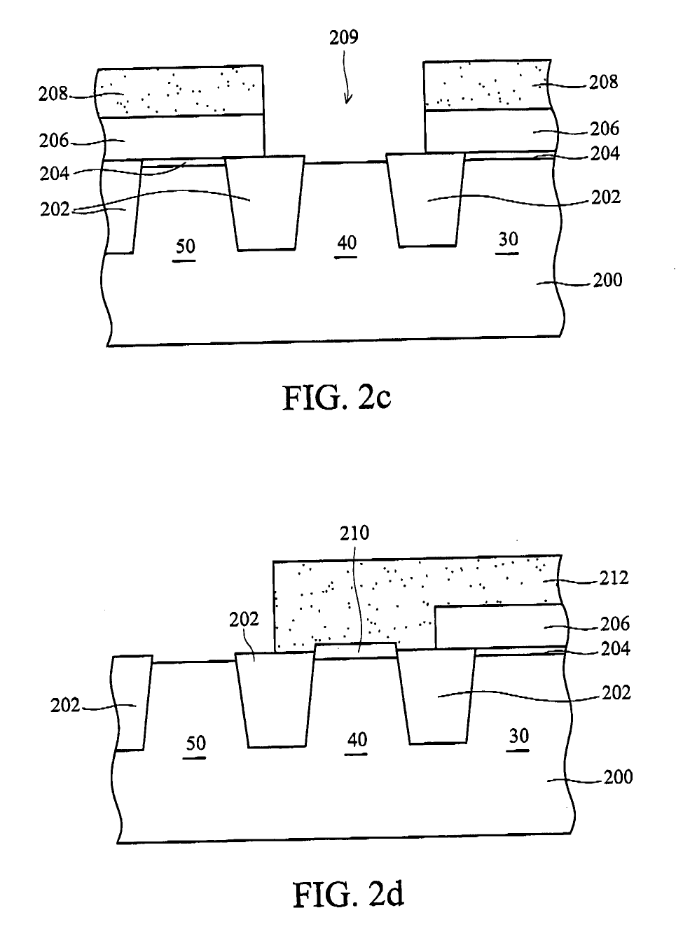

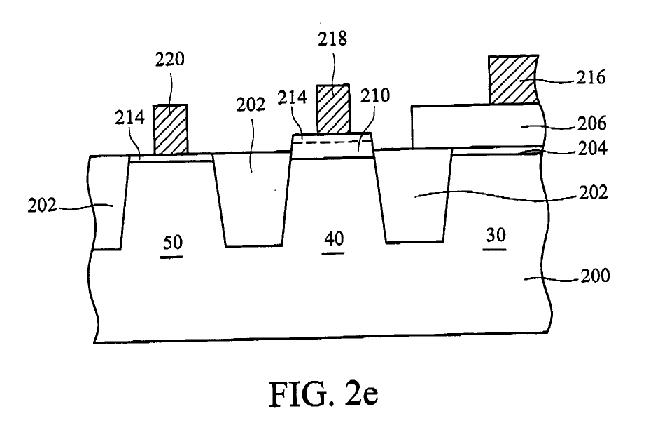

In FIG. 2a,a substrate 200, such as a silicon substrate or other semiconductor substrate, is provided. An isolation is region composed of a plurality of isolation structures 202 is formed within the substrate 200 by conventional isolation technology.

For example, the isolation structures 202 can be a field oxide (FOX) formed by shallow trenches isolation (STI) or local oxidation of silicon (LOCOS), wherein STI is preferable. As a result, a plurality of active regions is defined on the substrate 200 and separated from each other by the isolation structures 202. Here, in order to simplify the diagram, three active regions 30, 40, and 50 and three isolation structures 202 are depicted in FIG. 2a. In the invention, the active region 30 is used as a device region for high voltage (for example, 40V) operation, such as a power device region. Moreover, the active region 40 is used as a device region for low voltage (for example, 5.0V) operation, such as an input/output (I/O) device region. Furthermore, the active region 50 is used as a device region for even lower voltage (for example, 2.5V) operation, such as a core device region. Additionally, prior to the step depicted in FIG. 2a, various ion implantations and annealing processes may be performed to form desired well regions within the substrate 200 for MOS device fabrication.

Next, in FIG. 2b, a thin oxide layer 204 is formed on the active regions 30, 40, and 50. Here, the thin oxide layer 204 can be formed by performing a thermal oxidation on the substrate 200 and has a thickness of about 40 to 60 Å. In the invention, the thin oxide layer 204 on the active region 30 is used as a portion of the gate dielectric layer for the subsequent high voltage device (for example, power device) fabrication.

Thereafter, a critical step of the invention is performed. A blanket dielectric layer 206 is formed on the isolation structures 202 and the oxide layer 204. In the invention, the dielectric layer 206 can be a thick oxide layer formed by conventional physical or chemical deposition technology. For example, the dielectric layer 206 is a high temperature oxide (HTO) layer formed by chemical vapor deposition using tetraethyl orthosilicate (TEOS) as a deposition precursor at a temperature of about 700 to 900° C. The dielectric layer 206 on the active region 30 is used as the major portion of the gate dielectric layer for the subsequent high voltage device fabrication. That is, in the invention, the gate dielectric layer of the high voltage device is a composite oxide layer comprising a thermal oxide layer 204 and an overlying high temperature oxide layer 206. The thickness of the dielectric layer 206 depends on the design rule for the high voltage device fabrication. In general, the dielectric layer 206 has a thickness of about 300 to 1200 Å if the operation voltage is about 20 to 40V. Since the major portion of the gate dielectric layer is formed by CVD rather than by thermal oxidation in the prior art, the thermal budget may be greatly reduced.

Next, in FIG. 2c, a masking layer 208, such as a photoresist layer, is formed on the blanket dielectric layer 206 by conventional lithography. The masking layer 208 has an opening to expose the underlying dielectric layer 206 on the active region 40. Thereafter, the exposed dielectric layer 206 and the underlying oxide layer 204 on the active region 40 is removed by conventional dry or wet chemical etching using the masking layer 208 as an etch mask to expose the substrate 200 on the active region 40. In the invention, for example, the exposed dielectric layer 206 and the underlying thin oxide layer 204 is removed by wet chemical etching using hydrofluoric acid (HF) or buffer oxide etching (BOE) solution as an etchant. Since the dielectric layer 206 is also deposited on the isolation structures 202 adjacent to the active region 40, the isolation structures 202 composed of oxides can be protected from the formation of recesses during the wet chemical etching.

Next, in FIG. 2d, the photoresist layer 208, which is no longer needed, is removed by conventional ashing or suitable solution. A thin oxide layer 210 is subsequently formed on the exposed substrate 200 on the active region 40. Here, the thin oxide layer 210 can be formed by performing a thermal oxidation on the substrate 200 and has a thickness of about 40 to 70 Å. In the invention, the thin oxide layer 210 on the active region 40 is used as a portion of the gate dielectric layer for the subsequent low voltage device (for example, I/O device) fabrication.

A blanket masking layer 212, such as a photoresist layer, is subsequently formed overlying the substrate 200. Next, the masking layer 212 is patterned by conventional lithography to expose the dielectric layer 206 on the active region 50. Thereafter, the exposed dielectric layer 206 and the underlying oxide layer 204 on the active region 50 is removed by conventional dry or wet chemical wet etching using the masking layer 212 as an etch mask to expose the substrate 200 on the active region 50. In the invention, the exposed dielectric layer 206 and the underlying oxide layer 204 can be removed by wet chemical etching using HF or BOE solution as an etchant. Also, since the dielectric layer 206 is also deposited on the isolation structures 202 adjacent to the active region 50, the isolation structures 202 composed of oxides can be protected from the formation of recesses during the wet chemical etching.

Finally, in FIG. 2e, a thin oxide layer 214 is subsequently formed on the exposed substrate 200 on the active region 50 and on the oxide layer 210 on the active region 40. Here, the thin oxide layer 214 can be formed by performing a thermal oxidation on the substrate 200 and the oxide layer 210, and has a thickness of about 40 to 60 Å if the operation voltage is about 2.5V. In the invention, the thin oxide layer 214 on the active region 50 is used as the gate dielectric layer for the subsequent low voltage device (for example, core device) fabrication. Moreover, the thin oxide layer 214 on the active region 40 is used as another portion of the gate dielectric layer for the subsequent I/O device fabrication. That is, the gate dielectric layer of the I/O device is composed of the oxide layer 214 and the underlying oxide layer 210, which has a thickness of about 80 to 130 Å if the operation voltage is about 5V. Next, poly gates 216, 218, and 220 are respectively formed on the gate dielectric layers corresponding to the high voltage device region 30 and the low voltage regions 40 and 50 by conventional processes. As a result, the integrated circuit gate dielectric layers with multiple thicknesses is completed.

According to the invention, the gate dielectric layer of the high voltage device is a composite oxide and the major portion of the gate dielectric layer is formed by CVD rather than by thermal oxidation in the prior art. Accordingly, the thermal budget is greatly reduced to reducing the fabricating cost.

Moreover, in the invention, the relatively thin thermal oxide layer is formed on the active regions firstly, rather than a relatively thick thermal oxide layer in the prior art, preventing rounding off of the corners of the STI structures and narrowing of the active regions.

Furthermore, the blanket dielectric layer formed by CVD can serve as a sacrificial layer to protect the underlying STI structures when exposing the substrate on the active regions by etching, thereby preventing recessing of the STI structures. Accordingly, reliability of the devices can be increased.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art) . Therefore, the scope of the appended claims should be accorded the broadest interpretation so as to encompass all such modifications and similar arrangements.

1. A method of forming dielectric layers with various thicknesses on a substrate, comprising the steps of:
providing a first device region and a second device region on the substrate;
growing a first oxide layer on the substrate;
depositing a dielectric layer with a first thickness on the first oxide layer, having a substantially planar top surface;
removing the dielectric layer and the underlying first oxide layer on the second device region to expose the substrate; and
growing a second oxide layer with a second thickness less than the first thickness on the substrate of the second device region.

2. The method of claim 1, wherein the substrate further comprises a third device region.

3. The method of claim 2, wherein the third device region is a core device region for low voltage operation.

4. The method of claim 2, further comprising the steps of:
removing the dielectric layer and the underlying first oxide layer on the third device region to expose the substrate; and
growing a third oxide layer with a third thickness less than the first thickness on the substrate of the third device region and on the second oxide layer.

5. The method of claim 4, wherein third oxide layer is grown by thermal oxidation.

6. The method of claim 4, wherein the third thickness is about 30 to 60 Å.

7. The method of claim 1, wherein the first device region is a power device region for high voltage operation.

8. The method of claim 1, wherein the second device region is an I/O device region for low voltage operation.

9. The method of claim 1, wherein the first oxide layer is grown by thermal oxidation.

10. The method of claim 1, wherein the dielectric layer is a high temperature oxide layer formed by CVD.

11. The method of claim 1, wherein the first thickness is about 300 to 3000 Å.

12. The method of claim 1, wherein second oxide layer is grown by thermal oxidation.

13. The method of claim 1, wherein the second thickness is about 40 to 70 Å.

14. A method of forming gate dielectric layers with various thicknesses on a substrate, comprising the steps of:
providing a first active region and a second active region on the substrate;
forming a first thermal oxide layer on the substrate;
depositing a blanket dielectric layer with a first thickness overlying the substrate, having a substantially planar top surface;
forming a first masking layer overlying the substrate except over the second active region;
etching the dielectric layer and the underlying first thermal oxide layer on the second active region using the first masking layer as an etch mask to expose the substrate;
removing the first masking layer;
forming a second thermal oxide layer with a second thickness less than the first thickness on the second active region; and
forming a first gate on the dielectric layer on the first active region and a second gate on the second thermal oxide layer on the second active region.

15. The method of claim 14, wherein the substrate further comprises a third active region.

16. The method of claim 15, wherein the third active region is separated from the second active region by a shallow trench isolation region.

17. The method of claim 15, wherein before forming the first and second gates, further comprising the steps of:
forming a second masking layer overlying the substrate except over the third active region;
removing the dielectric layer and the underlying first thermal oxide layer on the third active region to expose the substrate;
removing the second masking layer; and
forming a third thermal oxide layer with a third thickness less than the first thickness on the third active region and on the second thermal oxide layer.

18. The method of claim 17, wherein the second masking layer is a photoresist layer.

19. The method of claim 17, wherein the step of forming the first and second gates further comprises forming a third gate on the third thermal oxide layer on the third active region.

20. The method of claim 17, wherein the third thickness is about 30 to 60 Å.

21. The method of claim 14, wherein the first active region and the second active region are separated by a shallow trench isolation region.

22. The method of claim 14, wherein the dielectric layer is a high temperature oxide layer formed by CVD.

23. The method of claim 14, wherein the first thickness is about 300 to 3000 Å.

24. The method of claim 14, wherein the first masking layer is a photoresist layer.

25. The method of claim 14, wherein the second thickness is about 40 to 70 Å.

26. A method of forming an integrated circuit having gate oxide layers with multiple thicknesses, comprising the steps of:
providing a substrate having a first active region, a second active region, and a third active region;
performing a first oxidation to form a first oxide layer on the substrate;
depositing a blanket high temperature oxide layer with a first thickness overlying the substrate, having a substantially planar too surface;
forming a first photoresist layer on the high temperature oxide layer except over the second active region;
etching the high temperature oxide layer and the underlying first oxide layer on the second active region using the first photoresist layer as an etch mask to expose the substrate;
removing the first photoresist layer;
performing a second oxidation to form a second oxide layer with a second thickness less than the first thickness on the second active region;
forming a second photoresist layer overlying the substrate except over the third active region;
removing the high temperature oxide layer and the underlying first oxide layer on the third active region to expose the substrate;
removing the second photoresist layer;
performing a third oxidation to form a third oxide layer with a third thickness less than the first thickness on the third active region and on the second oxide layer on the second active region; and
forming a first gate on the high temperature oxide layer on the first active region, a second gate on the second oxide layer on the second active region, and a third gate on the third thermal oxide layer on the third active region.

27. The method of claim 26, wherein the first, second, and third active regions are separated by a shallow trench isolation region.

28. The method of claim 26, wherein the first thickness is about 300 to 3000 Å.

29. The method of claim 26, wherein the second thickness is about 40 to 70 Å

30. The method of claim 26, wherein the third thickness is about 30 to 60 Å.

31. The method of claim 26, wherein the high temperature oxide layer is formed by CVD.
